(19) United States
(12) Patent Application Publication
(10) Pub. No.: US 2014/0001438 A1
(43) Pub. Date: Jan. 2, 2014

(54) SEMICONDUCTOR DEVICES AND METHODS OF MANUFACTURING THE SAME

(71) Applicants: Joo-sung KIM, Seongnam-si (KR); Jun-youn KIM, Hwaseong-si (KR); Jae-won LEE, Seoul (KR); Hyo-ji CHOI, Seoul (KR); Young-jo TAK, Hwaseong-si (KR)

(72) Inventors: Joo-sung KIM, Seongnam-si (KR); Jun-youn KIM, Hwaseong-si (KR); Jae-won LEE, Seoul (KR); Hyo-ji CHOI, Seoul (KR); Young-jo TAK, Hwaseong-si (KR)

(21) Appl. No.: 13/837,336

(22) Filed: Mar. 15, 2013

(30) Foreign Application Priority Data
Jul. 2, 2012 (KR) 10-2012-0071971

(51) Int. Cl. H01L 29/15; H01L 21/02

(52) U.S. Cl. CPC H01L 29/151; H01L 21/02587
USPC 257/18; 438/478

(57) ABSTRACT

A semiconductor device includes a buffer structure on a silicon substrate, and at least one gallium nitride-based semiconductor layer on the buffer structure. The buffer structure includes a plurality of nitride semiconductor layers and a plurality of stress control layers that are alternately disposed with the plurality of nitride semiconductor layer. The plurality of stress control layers include a IV-IV group semiconductor material.

### CROSS-REFERENCE TO RELATED APPLICATIONS

This application claims the benefit of priority under 35 U.S.C. §119 from Korean Patent Application No. 10-2012-0071971, filed on Jul. 2, 2012, in the Korean Intellectual Property Office, the disclosure of which is incorporated herein by reference in its entirety.

### BACKGROUND

1. Field

The present disclosure relates to semiconductor devices and methods of manufacturing the semiconductor devices, and more particularly, to nitride-based semiconductor devices formed on a silicon substrate and methods of manufacturing the semiconductor devices.

2. Description of the Related Art

Nitride-based semiconductor devices generally use a sapphire substrate. However, a sapphire substrate is expensive, is too hard to manufacture chips, and has a low electric conductivity. Furthermore, it is difficult to manufacture a sapphire substrate with a large size because warpage occurs at high temperatures, due to low thermal conductivity of the sapphire substrate. In order to solve such problems, nitride-based semiconductor devices using a silicon (Si) substrate instead of a sapphire substrate have been developed.

Because a Si substrate has a higher thermal conductivity than a sapphire substrate, significant warpage of the Si substrate is not observed at a high temperature used for growing a nitride thin film, thereby making it possible to grow a large size thin film on the Si substrate. However, when a nitride thin film is grown on a Si substrate, a dislocation density may be increased due to a mismatch in lattice constants between the Si substrate and the nitride thin film and cracks may occur due to a mismatch in thermal expansion coefficients between the Si substrate and the nitride thin film. Accordingly, many methods for reducing dislocation densities and preventing cracks have been studied. In order to use a Si substrate, there is a need for a method of preventing cracks due to tensile stress generated by a thermal expansion difference.

### SUMMARY

The present disclosure relates to semiconductor devices and methods of manufacturing the semiconductor devices, and more particularly, to nitride-based semiconductor devices formed on a silicon substrate and methods of manufacturing the semiconductor devices.

According to example embodiments, a semiconductor device includes a silicon substrate, a buffer structure on the silicon substrate, and at least one gallium nitride-based semiconductor layer on the buffer structure, wherein the buffer structure includes a plurality of nitride semiconductor layers, and a plurality of stress control layer alternately disposed with the plurality of nitride semiconductor layers. The plurality of stress control layer includes a IV-IV group semiconductor material.

In the buffer structure, at least one nitride semiconductor layer and at least one stress control layer may be alternately stacked to form a superlattice.

In the buffer structure, one stress control layer and one nitride semiconductor layer may be alternately and repeatedly stacked.

The stress control layer may include α-SiC, and the nitride semiconductor layer may include at least one of AlGaN, InGaN, and GaN.

In the buffer structure, one stress control layer and at least two nitride semiconductor layers having different compositions may be alternately and repeatedly stacked.

The stress control layer may include α-SiC, the nitride semiconductor layers may include at least one of AlGaN, InGaN, GaN and combinations thereof.

In the buffer structure, one stress control layer and at least two nitride semiconductor layers having different compositions are alternately and repeatedly stacked.

The stress control layer may include α-SiC, the at least two nitride semiconductor layers may include a first nitride semiconductor layer and a second nitride semiconductor layer, the first nitride semiconductor layer may include AlGaN, and the second nitride semiconductor layer may include InGaN.

The stress control layer may include α-SiC.

The nitride semiconductor layer may include a AlₓIn_{y}Ga_{1-x-y}N layer (where 0≦X≦1 and 0≦Y1).

The semiconductor device may further include a nitride nucleation formation layer on the silicon substrate, wherein the buffer structure is on the nitride nucleation formation layer. The nitride nucleation formation layer may include AlN.

The the plurality of nitride semiconductor layers may include a plurality of AlₓIn_{y}Ga_{1-x-y}N layers (where 0≦X≦1 and 0≦Y1≦1) of which compositions of the AlₓIn_{y}Ga_{1-x-y}N layers gradually or consecutively change in a direction extending from a lowermost surface of the buffer structure towards an uppermost surface of the buffer structure.

The plurality of nitride semiconductor layers may include at least one of AlGaN, InGaN, and GaN.

The stress control layer may have a thickness of a few angstroms (Å) through hundreds of nanometers (nm).

The stress control layer may include α-SiC.

The stress control layer may be located at least one of the highest layer and lowest layer of the buffer structure.

The semiconductor device may further include a nitride nucleation formation layer on the silicon substrate, wherein the buffer structure is on the nitride nucleation formation layer.

The nitride nucleation formation layer may include AlN.

According to example embodiments, a semiconductor device includes a buffer structure on a silicon substrate, and at least one gallium nitride-based semiconductor layer on the buffer structure. The buffer structure includes at least one nitride semiconductor layer configured to apply a compressive stress, and at least one stress control layer alternately disposed with the at least one nitride semiconductor layer configured to apply the compressive stress. The at least one nitride semiconductor layer may be a group (III) nitride semiconductor layer, and the at least one stress control layer may include a IV-IV group semiconductor material.

The group (III) nitride semiconductor layer may be a GaN-based semiconductor layer.

According to example embodiments, a method of forming a semiconductor device, the method includes: forming a buffer structure including a plurality of nitride semiconductor layers and a plurality of stress control layers on a silicon substrate, wherein the plurality of nitride semiconductor layers and the plurality of stress control layers are alternately disposed and the plurality of stress control layers each include an IV-IV group semiconductor material; and forming at least one gallium nitride-based semiconductor layer on the buffer structure.

The method may further include removing at least some layers of the buffer structure.

The buffer structure may include a structure in which a nitride semiconductor layer and a stress control layer are alternately and repeatedly stacked to form a superlattice or a plurality of nitride semiconductor layers are formed so that the compositions thereof are step-by-step or continuously changed, wherein the nitride semiconductor layer comprises AlₓIn_{y}Ga_{1-x-y}N where 0≦X≦1 and 0≦Y≦1.

The buffer structure may include a structure in which a stress control layer and a nitride semiconductor layer are alternately and repeatedly stacked, wherein the stress control layer comprises α-SiC and the nitride semiconductor layer comprises any one of AlGaN, InGaN, and GaN.

The buffer structure may include a structure in which a stress control layer and at least two nitride semiconductor layers having different compositions are alternately and repeatedly stacked, wherein the stress control layer comprises α-SiC, the at least two nitride semiconductor layers comprises a first nitride semiconductor layer and a second nitride semiconductor layer, the first nitride semiconductor layer comprises AlGaN, and the second nitride semiconductor layer comprises InGaN.

A semiconductor device according example embodiments includes a buffer structure disposed on the silicon substrate, which includes a plurality of nitride semiconductor layers and a plurality of stress control layers including a IV-IV group semiconductor material, wherein the nitride semiconductor layer and the stress control layer are alternately and repeatedly deposited, thereby applying a compressive stress while forming a gallium nitride-based semiconductor layer. The buffer structure may reduce defect generation due to lattice unconformity and may suppress cracks due to a thermal expansion coefficient difference, and thus a gallium nitride-based semiconductor layer having high quality may be formed on the buffer structure.

### BRIEF DESCRIPTION OF THE DRAWINGS

Example embodiments will be more clearly understood from the following detailed description taken in conjunction with the accompanying drawings. FIGS. 1-6 represent non-limiting, example embodiments as described herein.

FIG. 1 schematically illustrates a semiconductor device according to example embodiments;

FIG. 2 schematically illustrates an example of a buffer structure of FIG. 1;

FIGS. 3 through 6 illustrate various example embodiments of a buffer structure, which are applicable to the semiconductor device of FIG. 1; and

FIGS. 7A through 7D illustrate a method of manufacturing a semiconductor device, according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure relates to semiconductor devices, and more particularly, to nitride-based semiconductor devices formed on a silicon substrate.

A gallium nitride (GaN) thin film that is formed on a silicon substrate reduces a defect and wafer bowing that are caused by a lattice constant difference between the silicon substrate and a thin film, and a buffer layer is formed to suppress cracks that are caused by a thermal expansion coefficient difference.

Generally, the buffer layer may be formed of an AlN nucleation layer, in which Ga is not included, and a nitride stress-compensating layer (e.g., AlₓGa₁₋ₓN (where 0<x≦1), by a metal organic chemical vapor deposition (MOCVD) process.

The nitride stress-compensating layer compensates for a thermal tensile stress occurring during cooling by applying a compressive stress during growing thereof by using the composition, thickness, growing condition (for example, temperature), and structure (for example, a superlattice) of an AlₓGa₁₋ₓN layer and a combination thereof. In addition, the nitride stress-compensating layer reduces a large number of defects density that occur due to the interface and lattice unconformity between the silicon substrate and the AlN nucleation layer.

When forming a GaN layer on the grown buffer layer, it is necessary to increase the thickness of the GaN layer to control dislocation and to increase crystallinity. In this case, if an additional compressive stress is applied by inserting an intermediate layer, the dislocation due to the increase in thickness of the GaN layer may be decreased and cracks due to a tensile stress during cooling may be prevented. Generally, a layer (e.g., an AlN layer or an AlₓGa₁₋ₓN layer) of which a lattice constant is smaller than that of the GaN layer is used as the intermediate layer while growing the GaN layer.

However, the buffer layer that is used for growing the GaN layer on the silicon substrate and the AlN layer or AlₓGa₁₋ₓN layer that is used as the intermediate layer have problems, such as low crystallinity and surface roughness, in a MOCVD condition for depositing GaN, and thus, a new material and a new buffer structure are needed.

According to a semiconductor device according to example embodiments, a new buffer structure obtained by forming α-SiC having a Wurtzite structure (e.g., 4H or 6H) in-situ through MOCVD is provided. A SiC material of a IV-IV group may be epitaxially grown in the middle of epitaxial growth of a III-V group nitride semiconductor.

A buffer structure including α-SiC according to example embodiments may be applied to all existing buffers structures that are used to deposit GaN on silicon.

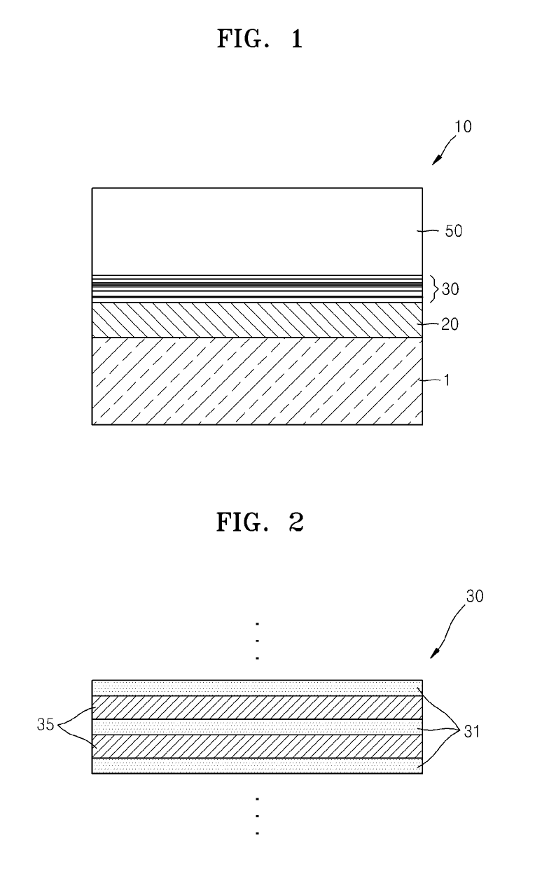

FIG. 1 schematically illustrates a semiconductor device according to example embodiments. FIG. 2 schematically illustrates an example of the buffer structure of FIG. 1.

Referring to FIG. 1, a semiconductor device 10 includes a silicon substrate 1, a buffer structure 30 disposed on the silicon substrate 1, and at least one gallium nitride-based semiconductor layer 50 formed on the buffer structure 30. The buffer structure 30 may include a plurality of nitride semiconductor layers 35 and a plurality of stress control layers 31 that are alternately disposed with the plurality of nitride semiconductor layers 35. The plurality of stress control layers 31 include a IV-IV group semiconductor material. The semiconductor device 10 may further include a nitride nucleation formation layer 20 between the silicon substrate 1 and the buffer structure 30.

The silicon substrate 1 may be a substrate including silicon Si having (111) crystal face and may have a large diameter. For example, the silicon substrate 1 may have a diameter that is more than 8 inches. The silicon substrate 1 may be doped with, for example, P-type or N-type impurities. The P-type impurities may include at least one selected from the group consisting of B, Al, Mg, Ca, Zn, Cd, Hg, Ga and elements having similar properties, and the N-type impurities may include at least one selected from the group consisting of As, P, and elements having similar properties. When the silicon substrate 1 is highly doped with the P-type impurities, a phenomenon by which the silicon substrate 1 is warped may be reduced. The silicon substrate 1 may be cleaned by using a mixture of sulfuric acid and hydrogen peroxide, hydrofluoric acid, deionized water, or the like. By cleaning the silicon substrate 1, impurities (e.g., metal, organic matter, or the like) and a natural oxide film may be removed. Thus, the surface of the silicon substrate 1 is terminated with hydrogen and thus may be put into a state suitable for epitaxial growth. The silicon substrate 1 may be removed during, or after, the manufacture of the semiconductor device 10.

The nitride nucleation formation layer 20 is disposed on the silicon substrate 1 and prevents a melt-back phenomenon that occurs as the silicon substrate 1 and a nitride semiconductor layer of the buffer structure 30, which includes gallium, react with each other at a high temperature. In addition, the nitride nucleation formation layer 20 may perform a function that enables the buffer structure 30 or the gallium nitride-based semiconductor layer 50 to be formed thereon to be well wetted. The nitride nucleation formation layer 20 may include, for example, AlN. The melt-back phenomenon is a phenomenon by which, in the case where silicon and a material including Ga (e.g., AlₓGa₁₋ₓN or the like) directly contact each other when growing the material including Ga (e.g., AlₓGa₁₋ₓN or the like) on the silicon substrate 1, the silicon diffuses into the material including Ga and thus the surface of the silicon substrate 1 is etched.

The buffer structure 30 is for applying a compressive stress during the growing of the semiconductor layer 50 to reduce defect generation due to lattice unconformity, suppressing a crack due to thermal expansion coefficient difference, and in addition, growing the semiconductor layer 50 having high quality. As schematically illustrated in FIG. 2 as an example, the buffer structure 30 includes the alternately disposed nitride semiconductor layers 35 and stress control layers 31 each including an IV-IV group semiconductor material. That is, at least one nitride semiconductor layer and one stress control layer form a pair that may be repeatedly deposited. A thickness and average lattice constant of each of the layers constituting the buffer structure 30 may be determined so that the sum of internal stresses of the layers equals the compressive stress.

In the buffer structure 30, the nitride semiconductor layers 35 and the stress control layers 31 may be alternately deposited to form a superlattice. The superlattice is formed when at least two layers formed of different materials form a pair, and the pair is repeatedly deposited at least twice. In this case, each of the nitride semiconductor layers 35 may be formed of a single layer, or may be formed of at least two nitride semiconductor layers having different lattice constants due to different compositions. Although in FIG. 2, each of the nitride semiconductor layers 35 is illustrated as a single layer for convenience sake, example embodiments are not limited thereto. That is, each of the nitride semiconductor layers 35 may be formed of at least two nitride semiconductor layers having different lattice constants.

As another example, the nitride semiconductor layers 35 and the stress control layers 31 are alternately deposited, and the composition of the nitride semiconductor layers 35 may be changed to form a graded buffer structure. For example, the nitride semiconductor layers 35 may be formed so that an average lattice constant increases from the lowest semiconductor layer toward the highest semiconductor layer. Also, in this case, each of the nitride semiconductor layers 35 may be formed of a single layer, or may be formed of at least two nitride semiconductor layers having different lattice constants due to different compositions.

In the above buffer structure 30, the nitride semiconductor layers 35 may include AlₓIn_{y}Ga_{1-x-y}N (where 0≦X≦1 and 0≦Y≦1). For example, the nitride semiconductor layers 35 may include at least one of AlGaN, GaN, and InGaN.

For example, each of the stress control layers 31 may have a thickness of a few angstroms (Å) through hundreds of nanometers (nm) and may be formed through epitaxial growth by using α-SiC.

In order to form an α-SiC stress control layer 31 through the epitaxial growth in a MOCVD reactor, a reaction material including silicon (Si) and carbon (C) is injected into the MOCVD reactor. A material including Si (e.g., SiH₄, Si₂H₆, or DTBSi (DiTertiaryButylSilane, C₈H₂OSi)) that is a MO source, and a material including C (e.g., CH₃, CH₆, C₄H₁₀, C₂H₂, TMS (CH₃)₄Si, CH₄, CBr₄, etc.) may be used as reaction sources. The thickness of the α-SiC stress control layer 31 may be adjusted to have a few angstroms (Å) through hundreds of nanometers so that the buffer structure 30 has a desired compressive stress.

The α-SiC stress control layer 31 as described above may be formed in-situ in the MOCVD reactor in which the nitride semiconductor layers 35 are formed or the gallium nitride-based semiconductor layer 50 is formed.

In this case, SiC that is deposited on the nitride nucleation formation layer 20 or on the nitride semiconductor layers 35 based on gallium nitride (e.g., AlGaN or the like) is grown as 4H or 6H polytype α-SiC in a hexagonal polytype, unlike 3C polytype β-SiC (where a lattice parameter is 4.359 Å) that is deposited on silicon, and thus, epitaxial growth of SiC having a hexagonal structure become possible.

FIG. 2 shows the case where the buffer structure 30 includes three α-SiC stress control layers 31 and two nitride semiconductor layers 35, which are alternately stacked, and a first layer of the buffer structure 30 is the α-SiC stress control layer 31. However, the case is shown as an example, and the number of stress control layers 31, the number of nitride semiconductor layers 35, the order of stack of the stress control layers 31 and nitride semiconductor layers 35, and the thickness and lattice constant of each layer may be variously changed within the range in which a desired compressive stress may be obtained.

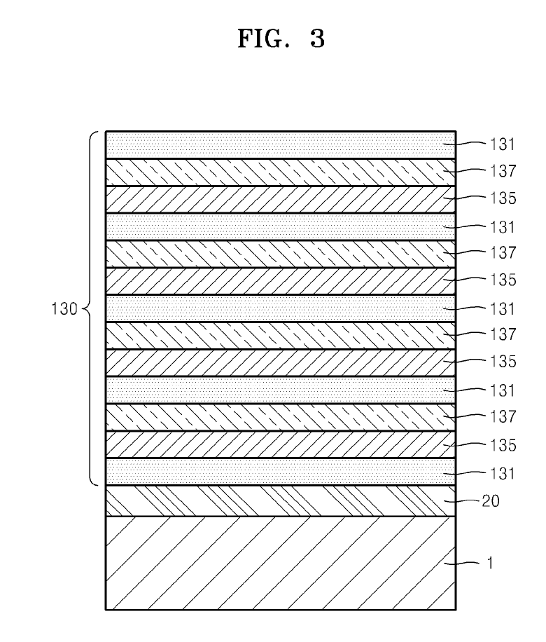

FIGS. 3 through 6 illustrate various example embodiments of buffer structures applicable to the semiconductor device of FIG. 1.

FIGS. 3 through 5 show the cases where the buffer structures each form a superlattice structure, and FIG. 6 shows the case where a buffer structure forms a graded buffer structure.

FIG. 3 illustrates a buffer structure according to example embodiments.

Referring to FIG. 3, a buffer structure 130 may include stress control layers 131, first nitride semiconductor layers 135, and second nitride semiconductor layers 137 that have compositions different from those of the first nitride semiconductor layers 135. One of the stress control layer 131, one of the first nitride semiconductor layers 135, and one of the second nitride semiconductor layers 137 form a group that is repeatedly stacked.

The stress control layers 131 may be formed of α-SiC. The first nitride semiconductor layers 135 may be formed of, for example, AlGaN. The second nitride semiconductor layers 137 may be formed of, for example, InGaN. The AlGaN first nitride semiconductor layers 135 and the InGaN second nitride semiconductor layers 137 may be located between two α-SiC stress control layers 131. The order of stack of the AlGaN first nitride semiconductor layers 135 and the InGaN second nitride semiconductor layers 137 may be changed with each other.

In this case, the group of the α-SiC stress control layer 131, the AlGaN first nitride semiconductor layer 135, and the InGaN second nitride semiconductor layer 137 may be repeatedly deposited to form a superlattice.

FIG. 3 shows the case where two nitride semiconductor layers (i.e., the first nitride semiconductor layer 135 and the second nitride semiconductor layer 137) are located between two stress control layers 131. However, the case is shown as an example, and two kinds of nitride semiconductor layers having different compositions may be repeatedly deposited a plurality of times between two stress control layers 131, or three or more kinds of nitride semiconductor layers having different compositions may be located between two stress control layers 131.

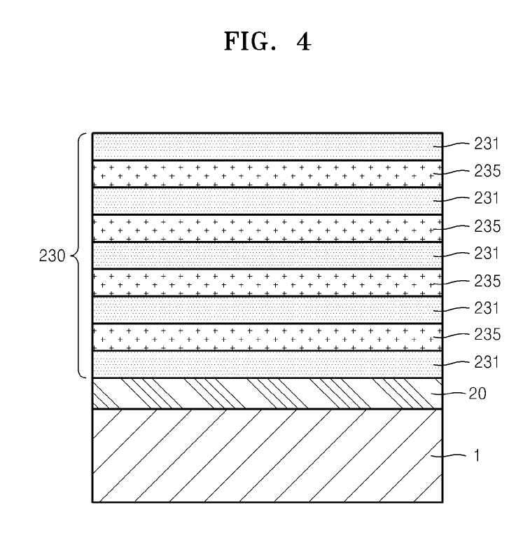

FIG. 4 illustrates a buffer structure according to other example embodiments.

Referring to FIG. 4, a buffer structure 230 includes stress control layers 231 and nitride semiconductor layers 235. The stress control layer 231 and the nitride semiconductor layer 235 form a pair that may be repeatedly deposited.

The stress control layers 231 may be formed of α-SiC. The nitride semiconductor layers 235 may be formed of, for example, GaN. In this manner, the stress control layers 231 may be formed of α-SiC, and the stress control layer 231 and the GaN single nitride semiconductor layer 235 may be alternately disposed. In this case, the α-SiC stress control layer 231 and the GaN single nitride semiconductor layer 235 may be repeatedly stacked to form a superlattice.

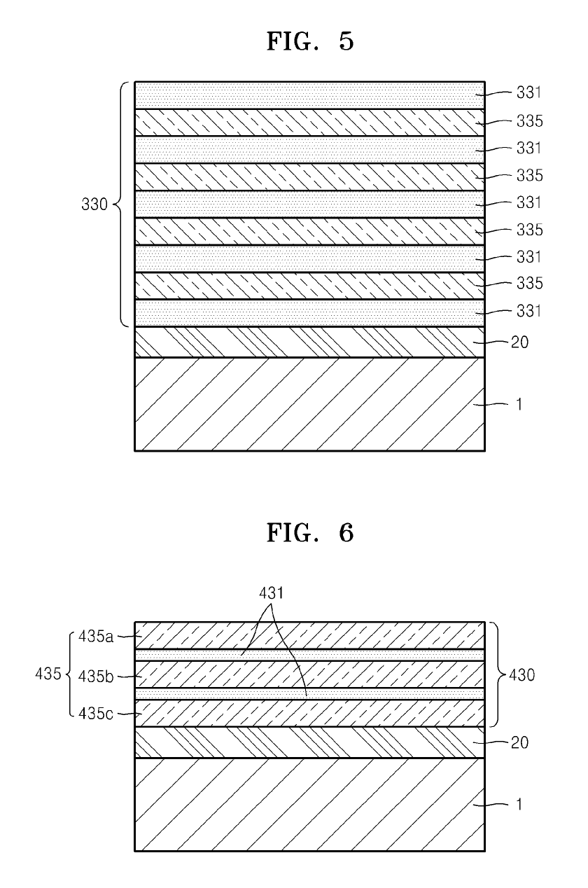

FIG. 5 illustrates a buffer structure according to yet other example embodiments.

Referring to FIG. 5, a buffer structure 330 includes stress control layers 331 and nitride semiconductor layers 335, and the stress control layer 331 and the nitride semiconductor layer 335 form a pair that may be repeatedly stacked.

The stress control layers 331 may be formed of α-SiC. The nitride semiconductor layers 335 may be formed of, for example, InGaN. In this manner, the stress control layers 331 may be formed of α-SiC, and the stress control layer 331 and the InGaN single nitride semiconductor layer 335 may be alternately disposed. In this case, the stress control layer 331 and the InGaN single nitride semiconductor layer 335 may be repeatedly stacked to form a superlattice.

FIGS. 3 through 5 show the cases where first and last layers of each of the buffer structures 130, 230, and 330 are the stress control layers 131, 231, and 331 formed of α-SiC. However, the cases are shown as examples, and the stack number of stress control layers, the stack number of nitride semiconductor layers, the order of stack of the stress control layers and nitride semiconductor layers, and the thickness and lattice constant of each layer may be variously changed within the range in which a desired compressive stress may be obtained.

FIG. 6 illustrates a buffer structure according to still other example embodiments.

Referring to FIG. 6, a buffer structure 430 includes a plurality of stress control layers 431 and a plurality of nitride semiconductor layers 435, and the single stress control layer 431 and the single nitride semiconductor layer 435 form a pair that may be repeatedly stacked.

The stress control layers 431 may be formed of α-SiC. The compositions of the plurality of nitride semiconductor layers 435 may gradually or consecutively change from the lowest layer toward the highest layer.

The plurality of nitride semiconductor layers 435 may include first through third nitride semiconductor layers 435a, 435b, and 435c, and the stress control layers 431 may be located between the first and second nitride semiconductor layers 435a and 435b and between the second and third nitride semiconductor layers 435b and 435c, respectively. The first nitride semiconductor layer 435a may include Alₓ₁In_{y1}Ga_{1-x1-y1}N (where 0≦X1≦1 and 0≦Y1≦1). The second nitride semiconductor layer 435b may include Alₓ₂In_{y2}Ga_{1-x2-y2}N (where 0≦X2≦1 and 0≦Y2≦1). The third nitride semiconductor layer 435c may include Alₓ₃In_{y3}Ga_{1-x3-y3}N (where 0≦X3≦1 and 0≦Y3≦1). In this case, the condition where X1≠X2≠X3 may be satisfied when X1, X2, and X3 are not zero, the condition where Y1≠Y2≠Y3 may be satisfied when Y1, Y2, and Y3 are not zero, and the compositions of the first through third nitride semiconductor layers 435a, 435b, and 435c may be gradually or consecutively changed.

For example, when forming the first through third nitride semiconductor layers 435a, 435b, and 435c to include any one of AlGaN, AlInGan, and InGaN, the first through third nitride semiconductor layers 435a, 435b, and 435c may be formed so that the compositions thereof are gradually or consecutively changed while including the same material.

FIG. 6 shows the case where the plurality of nitride semiconductor layers 435 include the first through third nitride semiconductor layers 435a, 435b, and 435c. However, the number of nitride semiconductor layers may be increased or decreased. In addition, although FIG. 6 shows an example where the nitride semiconductor layer 435 is formed first on the nitride nucleation formation layer 20, the stress control layer 431 may be formed first on the nitride nucleation formation layer 20. In addition, although FIG. 6 shows an example where a last layer of the buffer structure 430 is the nitride semiconductor layer 435, the last layer of the buffer structure 430 may be the stress control layer 431.

Referring back to FIG. 1, the gallium nitride-based semiconductor layer 50 may be formed on the buffer structure 30, 130, 230, 330, or 430. The gallium nitride-based semiconductor layer 50 that is formed based on gallium nitride indicates a semiconductor layer that includes gallium nitride (GaN), aluminum gallium nitride (AlGaN), indium gallium nitride (InGaN), aluminum indium gallium nitride (AlInGaN), or an alloy of gallium nitride.

In the semiconductor device 10 according to example embodiments, the gallium nitride-based semiconductor layer 50 may be formed with a desired thickness by reducing a tensile stress when forming the gallium nitride-based semiconductor layer 50 on the silicon substrate 1. In addition, a large diameter wafer may be manufactured using the silicon substrate 1.

The semiconductor device 10 according to the example embodiments may be applied to various devices such as a light-emitting diode, a Schottky diode, a laser diode, a field effect transistor, a power device, etc.

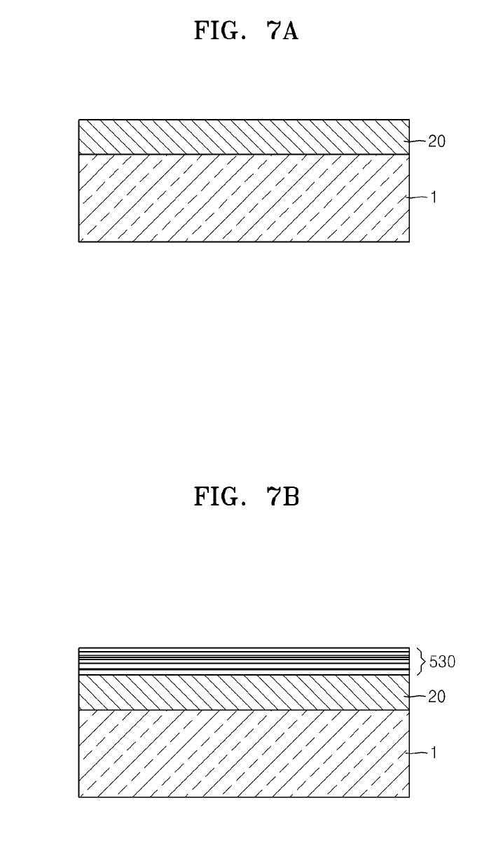

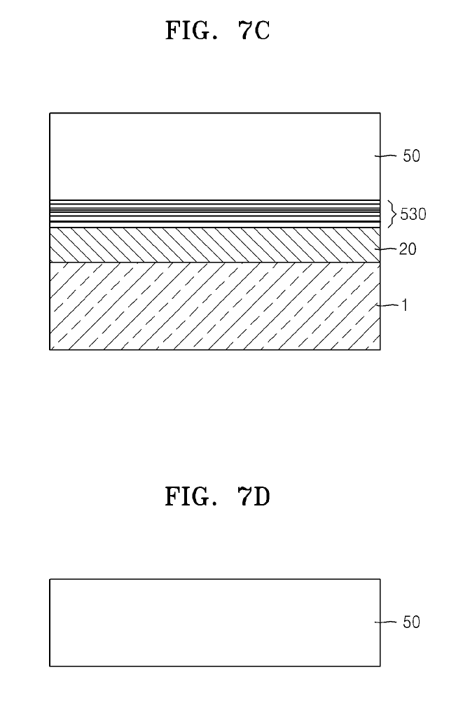

Below, a method of manufacturing a semiconductor device according to an embodiment of the present invention is described with reference to FIGS. 7A through 7D. A silicon substrate 1, a nitride nucleation formation layer 20, and a semiconductor layer 50 refer to the descriptions of the semiconductor device 10 according to the embodiment, which is described above with reference to FIGS. 1 through 6, and thus possible repetitive description thereof will be omitted.

In order to manufacture a semiconductor device, the silicon substrate(1) is prepared as shown in FIG. 7A. As described above, the silicon substrate 1 may be a substrate including silicon Si having (111) crystal face and may have a large diameter. The silicon substrate 1 may be doped with p-type or n-type impurities. The silicon substrate 1 may be cleaned by using a mixture of sulfuric acid and hydrogen peroxide, hydrofluoric acid, deionized water, or the like. By cleaning the silicon substrate 1, impurities (e.g., metal, organic matter, or the like) and a natural oxide film may be removed. Thus, the surface of the silicon substrate 1 is terminated with hydrogen and thus may be put into a state suitable for epitaxial growth. The silicon substrate 1 may be removed during, or after, the manufacture of the semiconductor device 10.

The nitride nucleation formation layer 20 may be disposed on the silicon substrate 1. The nitride nucleation formation layer 20 may include, for example, AlN. The method of manufacturing the semiconductor device may be performed without the nitride nucleation formation layer 20.

Referring to FIG. 7B, a buffer structure 530 is formed on the silicon substrate 1. The buffer structure 530 is for applying a compressive stress during the growing of the semiconductor layer 50 to reduce defect generation due to lattice unconformity, suppressing a crack due to thermal expansion coefficient difference, and in addition, growing the semiconductor layer 50 having high quality. The buffer structure 530 may have the buffer structures 30, 130, 230, 330, or 430 described with reference to FIGS. 1 through 6.

The buffer structure 330 includes, for example, a plurality of nitride semiconductor layers and a plurality of stress control layers 31 each including an IV-IV group semiconductor material. The nitride semiconductor layers and the stress control layers 31 are alternately disposed. That is, at least one nitride semiconductor layer and one stress control layer form a pair that may be repeatedly deposited. A thickness and average lattice constant of each of the layers constituting the buffer structure 530 may be determined so that the sum of internal stresses of the layers equals the compressive stress.

In the buffer structure 530, the nitride semiconductor layers and the stress control layers may be alternately deposited to form a superlattice.

In the buffer structure 530, the nitride semiconductor layers and the stress control layers are alternately deposited, and the composition of the nitride semiconductor layers may be changed to form a graded buffer structure. For example, the nitride semiconductor layers may be formed so that an average lattice constant increases from the lowest semiconductor layer toward the highest semiconductor layer. Also, in this case, each of the nitride semiconductor layers may be formed of a single layer, or may be formed of at least two nitride semiconductor layers having different lattice constants due to different compositions.

In the above buffer structure 530, the nitride semiconductor layers may include AlₓIn_{y}Ga_{1-x-y}N (where 0≦X≦1 and 0≦Y≦1). For example, the nitride semiconductor layers may include at least one of AlGaN, GaN, and InGaN.

For example, each of the stress control layers 31 may have a thickness of a few angstroms (Å) through hundreds of nanometers (nm) and may be formed through epitaxial growth by using α-SiC.

In order to form an α-SiC stress control layer 31 through the epitaxial growth in a MOCVD reactor, a reaction material including silicon (Si) and carbon (C) is injected into the MOCVD reactor. A material including Si (e.g., SiH₄, Si₂H₆, or DTBSi (DiTertiaryButylSilane, C₈H₂OSi)) that is a MO source, and a material including C (e.g., CH₃, CH₆, C₄H₁₀, C₂H₂, TMS (CH₃)₄Si, CH₄, CBr₄, etc.) may be used as reaction sources. The thickness of the α-SiC stress control layer 31 may be adjusted to have a few angstroms (Å) through hundreds of nanometers so that the buffer structure 530 has a desired compressive stress.

The α-SiC stress control layer as described above may be formed in-situ in the MOCVD reactor in which the nitride semiconductor layers are formed or a gallium nitride-based semiconductor layer 50 is formed.

After forming the buffer structure 530 as described above, at least one gallium nitride-based semiconductor layer 50 is formed on the buffer structure 530 as shown in FIG. 7C.

The gallium nitride-based semiconductor layer 50 is formed on the buffer structure 530. The gallium nitride-based semiconductor layer 50 that is formed based on gallium nitride indicates a semiconductor layer that includes gallium nitride (GaN), aluminum gallium nitride (AlGaN), indium gallium nitride (InGaN), aluminum indium gallium nitride (AlInGaN), or an alloy of gallium nitride.

After forming the semiconductor layer 50 as described above, at least some layers of the buffer structure 530 may be removed as shown in FIG. 7D. FIG. 7D shows an example in which all layers constituting the buffer structure 530 are removed.

After removing at least some layers of the buffer structure 530, a next process for completing the manufacturing of the semiconductor device may be performed. Before removing at least some layers of the buffer structure 530, a supporting substrate (not shown) for supporting the semiconductor layer 50 may be combined with the semiconductor layer 50, and in this state, at least some layers of the buffer structure 530 may be removed.

In the operation of removing at least some layers of the buffer structure 530, the silicon substrate 1 and the nitride nucleation formation layer 20 may be removed together. A process for removing at least some layers of the buffer structure 530 may be performed after removing the silicon substrate 1.

When the buffer structure 530 is removed as described above, the semiconductor layer 50 remains. In this case, the semiconductor layer 50 includes at least one nitride semiconductor layer.

In a state where the silicon substrate 1 or the buffer structure 530 remains intact, a next process for completing the manufacturing of the semiconductor device may be performed with respect to the nitride semiconductor layer 50. That is, the semiconductor device manufactured by the method according to the current embodiment may at least one of include the silicon substrate 1 and the buffer structure 530.

According to the method of manufacturing a semiconductor device according to the above embodiment, the gallium nitride-based semiconductor layer 50 may be formed with a desired thickness by reducing a tensile stress when forming the gallium nitride-based semiconductor layer 50 on the silicon substrate 1. In addition, a large diameter wafer may be manufactured using the silicon substrate 1.

The method of manufacturing a semiconductor device according to the above embodiment may be used for manufacturing various devices such as a light-emitting diode, a Schottky diode, a laser diode, a field effect transistor, a power device, etc.

The foregoing is illustrative of example embodiments and is not to be construed as limiting thereof. Although a few example embodiments have been described, those skilled in the art will readily appreciate that many modifications are possible in example embodiments without materially departing from the novel teachings. Accordingly, all such modifications are intended to be included within the scope of the disclosure as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A semiconductor device comprising
a buffer structure on a silicon substrate; and
at least one gallium nitride-based semiconductor layer on the buffer structure,
wherein the buffer structure includes:
a plurality of nitride semiconductor layers; and
a plurality of stress control layers that are alternately disposed with the plurality of nitride semiconductor layers and include a IV-IV group semiconductor material.

2. The semiconductor device of claim 1, wherein in the buffer structure, at least one nitride semiconductor layer and at least one stress control layer is alternately stacked to form a superlattice.

3. The semiconductor device of claim 2, wherein in the buffer structure, one stress control layer and one nitride semiconductor layer are alternately and repeatedly stacked.

4. The semiconductor device of claim 3, wherein the stress control layer includes α-SiC, and the nitride semiconductor layer includes at least one of AlGaN, InGaN, GaN and combinations thereof.

5. The semiconductor device of claim 2, wherein in the buffer structure, one stress control layer and at least two nitride semiconductor layers having different compositions are alternately and repeatedly stacked.

6. The semiconductor device of claim 5, wherein the stress control layer includes α-SiC, the at least two nitride semiconductor layers include a first nitride semiconductor layer and a second nitride semiconductor layer, the first nitride semiconductor layer includes AlGaN, and the second nitride semiconductor layer includes InGaN.

7. The semiconductor device of claim 2, wherein the nitride semiconductor layer includes AlₓIn_{y}Ga_{1-x-y}N (where 0≦X≦1 and 0≦Y≦1).

8. The semiconductor device of claim 2, wherein the stress control layer includes α-SiC.

9. The semiconductor device of claim 2, further comprising a nitride nucleation formation layer on the silicon substrate,
wherein the buffer structure is on the nitride nucleation formation layer.

10. The semiconductor device of claim 9, wherein the nitride nucleation formation layer includes AlN.

11. The semiconductor device of claim 1, wherein the plurality of nitride semiconductor layers includes a plurality of AlₓIn_{y}Ga_{1-x-y}N layers (where 0≦X≦1 and 0≦Y1) of which compositions of the AlₓIn_{y}Ga_{1-x-y}N layers gradually or consecutively change in a direction extending from a lowermost surface of the buffer structure towards an uppermost surface of the buffer structure.

12. The semiconductor device of claim 11, wherein the plurality of nitride semiconductor layers include at least one of AlGaN, InGaN, and GaN.

13. The semiconductor device of claim 11, wherein the stress control layer has a thickness of a few angstroms (Å) through hundreds of nanometers (nm).

14. The semiconductor device of claim 11, wherein the stress control layer includes α-SiC.

15. The semiconductor device of claim 1, wherein the plurality of stress control layer include α-SiC.

16. The semiconductor device of claim 15, wherein the stress control layer is located at at least one of the highest layer and lowest layer of the buffer structure.

17. The semiconductor device of claim 1, further comprising a nitride nucleation formation layer on the silicon substrate,
wherein the buffer structure is on the nitride nucleation formation layer.

18. The semiconductor device of claim 17, wherein the nitride nucleation formation layer includes AlN.

19. A semiconductor device, comprising:
a buffer structure on a silicon substrate; and
at least one gallium nitride-based semiconductor layer on the buffer structure,
wherein the buffer structure includes,
at least one nitride semiconductor layer configured to apply a compressive stress, and
at least one stress control layer alternately disposed with the at least one nitride semiconductor layer configured to apply the compressive stress, the at least one nitride semiconductor layer is a group (III) nitride semiconductor layer, the at least one stress control layer including a IV-IV group semiconductor material.

20. The semiconductor device of claim 19, wherein the group (III) nitride semiconductor layer is a GaN-based semiconductor layer.

21. A method of forming a semiconductor device, the method comprising:
forming a buffer structure comprising a plurality of nitride semiconductor layers and a plurality of stress control layers on a silicon substrate, wherein the plurality of stress control layers include an IV-IV group semiconductor material and are alternately disposed with the plurality of nitride semiconductor layers; and
forming at least one gallium nitride-based semiconductor layer on the buffer structure.

22. The method of claim 21, further comprising removing at least some layers of the buffer structure.

23. The method of claim 21, wherein the buffer structure comprises a structure in which a nitride semiconductor layer and a stress control layer are alternately stacked to form a superlattice or a plurality of nitride semiconductor layers are formed so that the compositions thereof are gradually or consecutively changed, wherein the nitride semiconductor layer comprises AlₓIn_{y}Ga_{1-x-y}N where 0≦X≦1 and 0≦Y≦1.

24. The method of claim 23, wherein the buffer structure comprises a structure in which a stress control layer and a nitride semiconductor layer are alternately stacked, wherein the stress control layer comprises α-SiC and the nitride semiconductor layer comprises any one of AlGaN, InGaN, and GaN.

25. The method of claim 23, wherein the buffer structure comprises a structure in which a stress control layer and at least two nitride semiconductor layers having different compositions are alternately stacked, wherein the stress control layer comprises α-SiC, the at least two nitride semiconductor layers comprises a first nitride semiconductor layer and a second nitride semiconductor layer, the first nitride semiconductor layer comprises AlGaN, and the second nitride semiconductor layer comprises InGaN.
